(19) United States
(12) Patent Application Publication
(10) Pub. No.: US 2006/0141722 A1
(43) Pub. Date: Jun. 29, 2006

(54) Method of sequentially forming silicide layer and contact barrier in semiconductor integrated circuit device

(75) Inventor: Hyoung Yoon Kim, Chungcheongbuk-do (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Gangnam-gu (KR)

(21) Appl. No.: 11/319,709

(22) Filed: Dec. 29, 2005

(30) Foreign Application Priority Data
Dec. 29, 2004 (KR) 10-2004-0115767

(51) Int. Cl. H01L 21/336

(52) U.S. Cl. 438/299

(57) ABSTRACT

A method of sequentially forming a silicide layer and a contact barrier in a semiconductor device is provided. In the method, a pre-metal dielectric layer is deposited over an underlying structure that has a silicon substrate, a gate electrode on the substrate, and source/drain regions in the substrate. Contact holes are formed toward the gate electrode and the source/drain regions in the dielectric layer. Then, a metal layer for the silicide layer is selectively deposited on the bottom of the contact holes by using ion implantation, for example. Thereafter, the contact barrier is conformally deposited on entire exposed surface, and a heat-treatment process is performed to form the silicide layer from the metal layer.

This U.S. non-provisional application claims priority under 35 U.S.C. §119 from Korean Patent Application No. 2004-115767, which was filed in the Korean Intellectual Property Office on Dec. 29, 2004, the contents of which are incorporated by reference herein in its entirety.

### BACKGROUND OF THE INVENTION

1. Field of the Invention

The present invention relates generally to semiconductor device fabrication technology and, more particularly, to a method of sequentially forming a silicide layer and a contact barrier in a semiconductor integrated circuit (IC) device such as MOSFET.

2. Description of the Related Art

A semiconductor IC device has employed in general polysilicon as a gate electrode. However, as the critical dimension is rapidly reduced due to an increase of integration degree, the above conventional electrode materials may fail to satisfy lower contact resistance required for high-integrated devices.

Silicide (alloys of silicon and metals) has been introduced as contact materials in silicon device fabrication. Silicide combines advantageous features of metal contacts (e.g., significantly lower resistivity than polysilicon) and polysilicon contacts (e.g., no electromigration). Silicide may be formed from a variety of metals such as titanium (Ti), cobalt (Co), vanadium (V), chromium (Cr), zirconium (Zr), niobium (Nb), molybdenum (Mo), hafnium (Hf), etc. Among them, titanium silicide and cobalt silicide favorably rise as leading materials due to their excellent properties such as low resistivity, high melting point, good formability of thin film, good formability of line pattern, and thermal stability.

As is well known in the art, a silicide layer is formed by a salicide (i.e., self-aligned silicide) process in which silicide contacts are formed only in those areas in which deposited metal is in direct contact with silicon, hence, are self-aligned.

FIGS. 1A and 1B are cross-sectional views illustrating a convention method of forming a silicide layer in a semiconductor device.

Referring to FIG. 11A, a gate oxide layer 12 and a gate electrode 13 are formed on a silicon substrate 11. Source/drain regions 14 and 15 are formed in the silicon substrate 11, and further, TEOS oxide and silicon nitride form sidewall spacers 16 and 17 on sidewalls of the gate electrode 13. On this structure, a metal layer 18 is conformally deposited for forming a silicide layer.

Thereafter, as shown in FIG. 1B, the silicide layer 18a and 18b are formed on both the gate electrode 13 and the source/drain regions 14 and 15. Traditionally, a process of forming the silicide layer 18a and 18b includes a first heat-treating step, a cleaning step, and a second heat-treating step.

By performing the first heat-treating step at a relatively lower temperature, the metal layer 18, in FIG. 1A, is reacted with silicon in the gate electrode 13 and the source/drain regions 14 and 15, and thereby turned into the silicide layer 18a and 18b. The cleaning step is performed to remove non-silicide parts of the metal layer. Then, the silicide layer 18a and 18b are subjected to the second heat-treating step performed at a relatively higher temperature for stability.

Thereafter, although not depicted in drawings, a pre-metal dielectric (PMD) layer is deposited over the former structure and patterned to form contact holes toward the gate electrode and the source/drain regions. Then, a contact barrier is conformally deposited in the contact holes and annealed before the contact holes are filled with contact material.

### SUMMARY OF THE INVENTION

Exemplary, non-limiting embodiments of the present invention provide a method of sequentially forming a silicide layer and a contact barrier in a semiconductor device not only to attain simpler processes, but also to form a thinner, more uniform silicide layer.

According to one exemplary embodiment of the present invention, the method comprises depositing a pre-metal dielectric layer over an underlying structure that has a silicon substrate, a gate electrode on the substrate, and source/drain regions in the substrate, and forming contact holes toward the gate electrode and the source/drain regions in the dielectric layer. The method further comprises selectively depositing a metal layer on the bottom of the contact holes, conformally depositing a contact barrier on entire exposed surface, and performing a heat-treatment to form a silicide layer from the metal layer.

In the method, the selective depositing of the metal layer can use ion implantation. The ion implantation can be performed with high dose and low energy.

The metal layer can be formed of titanium (Ti), cobalt (Co), vanadium (V), chromium (Cr), zirconium (Zr), niobium (Nb), molybdenum (Mo), or hafnium (Hf). The contact barrier can be formed of titanium (Ti) and titanium nitride (TiN).

In the method, the heat-treatment can, if desired, be performed once only at a high temperature, or alternatively, can, if desired, be performed twice at a low temperature and at a high temperature. Additionally, the heat-treatment can be performed in an in-situ chamber.

### BRIEF DESCRIPTION OF THE DRAWINGS

FIGS. 1A and 1B are cross-sectional views illustrating a convention method of forming a silicide layer in a semiconductor device.

FIGS. 2A to 2D are cross-sectional views illustrating a method of sequentially forming a silicide layer and a contact barrier in accordance with an exemplary embodiment of the present invention.

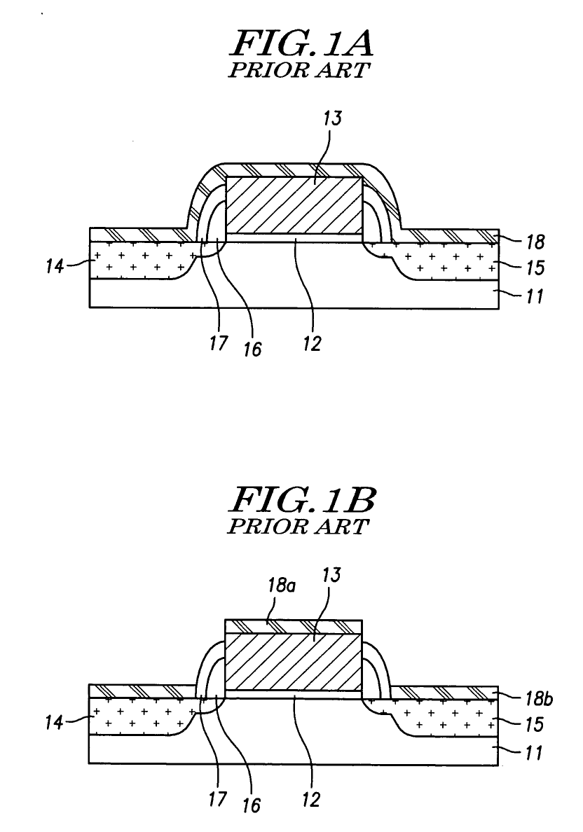

### DETAILED DESCRIPTION OF EXEMPLARY EMBODIMENTS OF THE INVENTION

An exemplary, non-limiting embodiment of the present invention will now be described more fully hereinafter with reference to the accompanying drawings. This invention may, however, be embodied in many different forms and should not be construed as limited to the exemplary embodiment set forth herein. Rather, the disclosed embodiment is provided so that this disclosure will be thorough and complete, and will fully disclose the invention to those skilled in the art. The principles and features of this invention may be employed in varied and numerous embodiments without departing from the scope of the invention.

In is noted that well-known structures and processes are not described or illustrated in detail to avoid obscuring the essence of the present invention. It is also noted that the figures are not drawn to scale.

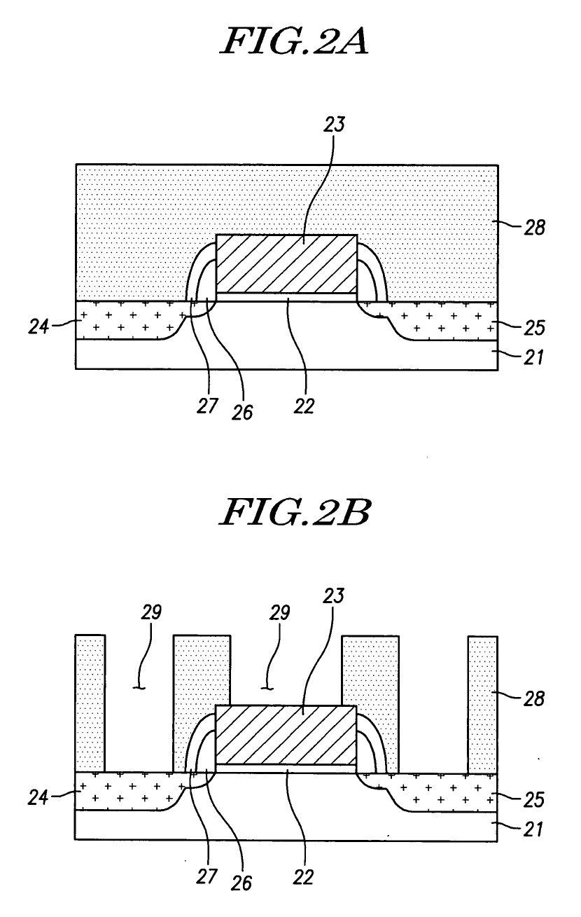

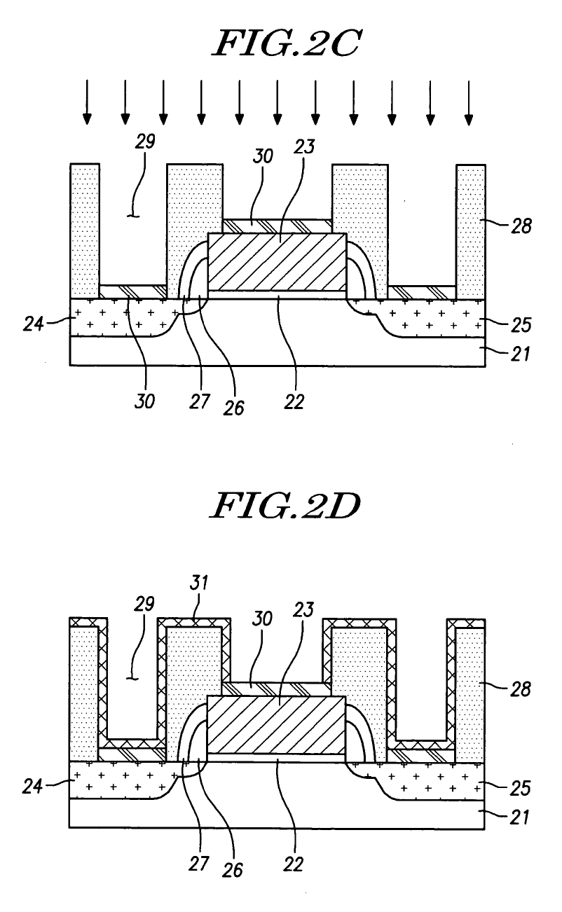

FIGS. 2A to 2D are cross-sectional views illustrating a method of sequentially forming a silicide layer and a contact barrier in accordance with an exemplary embodiment of the present invention.

Referring to FIG. 2A, a gate oxide layer 22 and a gate electrode 23 are formed on a silicon substrate 21. Although not illustrated, the silicon substrate 21 has active areas and isolation areas defined by an isolation oxide layer. The gate oxide layer 22 is thermally grown on the silicon substrate 21, and then in-situ doped polysilicon or undoped polysilicon is deposited thereon by a typical CVD process. Deposition of the undoped polysilicon is followed by a typical ion implanting process for doping. A deposited polysilicon layer is patterned together with the gate oxide layer 22 to form the gate electrode 23.

A lower impurity part of source/drain regions 24 and 25 are formed in the silicon substrate 21 by ion implantation, and sidewall spacers 26 and 27 are formed on sidewalls of the gate electrode 23 by deposition and blanket etching. For example, the sidewall spacers 26 and 27 are composed of TEOS oxide and silicon nitride. Then, a higher impurity part of the source/drain regions 24 and 25 are formed by ion implantation. Next, a pre-metal dielectric (PMD) layer 28 is deposited over the former structure. For example, the PMD layer 28 is formed of borophosphosilicate glass (BPSG) or undoped spin-on-glass (USG).

Referring to FIG. 2B, the PMD layer 28 is patterned to form contact holes 29 toward the gate electrode 23 and the source/drain regions 24 and 25. Then, as shown in FIG. 2C, a metal layer 30 is selectively deposited on the bottom of the contact holes, that is, on both the gate electrode 23 and the source/drain regions 24 and 25. Such selective deposition of the metal layer 30 uses ion implantation. The metal layer 30 can be formed of titanium (Ti), cobalt (Co), vanadium (V), chromium (Cr), zirconium (Zr), niobium (Nb), molybdenum (Mo), hafnium (Hf), etc, preferably titanium or cobalt. For thinner, more uniform deposition, ion implantation for the metal layer 30 can be performed with high dose and low energy.

Next, as shown in FIG. 2D, a contact barrier 31 is conformally deposited on the entire exposed surface. The contact barrier 31 can prevent the metal layer 30 from being oxidized in the subsequent heat-treatment. Additionally, the contact barrier 31 can act as a glue layer as well as a diffusion barrier in a subsequent contact formation. For example, the contact barrier 31 can be formed of titanium (Ti) and titanium nitride (TiN).

Thereafter, a heat-treatment process is performed to form the silicide layer from the metal layer 30. This heat-treatment can, if desired, be performed once only at a high temperature, or alternatively, can, if desired, be performed twice, i.e., at a low temperature and at a high temperature, in a typical in-situ chamber. Either case does not require a conventional cleaning step of removing non-silicide metal. Furthermore, this heat-treatment process combines conventional heat-treating steps that are separately implemented for the silicide layer and the contact barrier.

While this invention has been particularly shown and described with reference to an exemplary embodiment thereof, it will be understood by those skilled in the art that various changes in form and details may be made therein without departing from the spirit and scope of the invention as defined by the appended claims.

What is claimed is:

1. A method of sequentially forming a silicide layer and a contact barrier in a semiconductor device, the method comprising:
depositing a pre-metal dielectric layer over an underlying structure having a silicon substrate, a gate electrode on the substrate, and source/drain regions in the substrate;
forming contact holes toward the gate electrode and the source/drain regions in the dielectric layer;
selectively depositing a metal layer on the bottom of the contact holes;
conformally depositing a contact barrier on entire exposed surface; and
performing a heat-treatment to form a silicide layer from the metal layer.

2. The method of claim 1, wherein the selective depositing of the metal layer uses ion implantation.

3. The method of claim 2, wherein the ion implantation is performed with high dose and low energy.

4. The method of claim 1, wherein the metal layer is formed of a metal selected from the group consisting of titanium (Ti), cobalt (Co), vanadium (V), chromium (Cr), zirconium (Zr), niobium (Nb), molybdenum (Mo), and hafnium (Hf).

5. The method of claim 1, wherein the contact barrier is formed of titanium (Ti) and titanium nitride (TiN).

6. The method of claim 1, wherein the heat-treatment is performed once only at a high temperature.

7. The method of claim 1, wherein the heat-treatment is performed twice, once at a low temperature and once at a high temperature.

8. The method of claim 7, wherein the heat-treatment is performed in an in-situ chamber.
